(19) United States
(12) Patent Application Publication
(10) Pub. No.: US 2005/0118527 A1
(43) Pub. Date: Jun. 2, 2005

(54) Wide band gap semiconductor composite detector plates for x-ray digital radiography

(76) Inventors: Ze'ev Harel, Ra'anana (IL); Michael Schieber, Jerusalem (IL); Yehezkei Saado, Jerusalem (IL); Evgeny Meerson, Jerusalem (IL); Haim Hermon, Jerusalem (IL); Benjamin Joshua Reisman, Halamish (IL)

Correspondence Address: SQUIRE, SANDERS & DEMPSEY L.L.P, 600 HANSEN WAY, PALO ALTO, CA, 94304-1043, US

(21) Appl. No.: 10/481,192

(22) PCT Filed: Feb. 18, 2002
(86) PCT No.: PCT/IL02/00124

(30) Foreign Application Priority Data
Feb. 18, 2001 (IL) 141483
Jun. 19, 2001 (IL) 143849

(51) Int. Cl. G03C 1/76

(52) U.S. Cl. 430/270.1

(57) ABSTRACT

An imaging composition for radiation detection systems which includes an admixture of at least one non-heat treated, non-ground particulate semiconductor with a polymeric binder. The non-heat treated, non-ground particulate semiconductor is selected from mercuric iodide, lead iodide, bismuth iodide, thallium bromide and cadmium-zinc-telluride (CZT), and at least 90% of the semiconductor particulates have a grain size of less than 100 microns in their largest dimension. A radiation detector plate (10) for an imaging system includes a substrate (12) which serves as an electrode, at least one imaging composition layer (16) applied onto the substrate (12), and a second electrode (18) which is in electrical connection with the imaging composition (16) and connected (20, 22) to a high voltage bias.

### FIELD OF THE INVENTION

The present invention relates to wide band gap semiconductor-binder composites for use in detectors in X-ray digital imaging.

### BACKGROUND OF THE INVENTION

Lead iodide (Pbl₂), bismuth iodide (Bil₃), thallium bromide (TIBr) and mercuric iodide (Hgl₂), are well-known wide band gap semiconductors that exhibit properties which make them ideal for use in room temperature X-ray detection and imaging applications. These properties include a wide band gap (2.3, 2.2, 2.3 and 2.1 eV respectively), high atomic numbers Z, and low energy (below 5 eV) electron-hole pair formation. The wide energy band gap reduces the dark current at room temperature; the high atomic numbers permit good photon absorption and reduce radiation exposure; and the low energy for electron-hole pair formation produces a high X-ray-to-electrical charge ratio which conveys a high conversion coefficient.

The use of mercuric iodide as single crystal X-ray detectors is known but limited to relatively small area detectors due to the high cost of producing large single crystals. Moreover, mercuric iodide crystals are produced from the vapor phase and large crystals require long periods of time for growth. Finally, the sawing and polishing of these crystals can result in the loss of a large percentage, even a major portion, of the crystal. For applications requiring large detection areas, such as detectors having areas in excess of 100 cm², the use of polycrystalline mercuric iodide grains with their much lower production cost is very advantageous.

Polycrystalline Hgl₂ and Pbl₂ have been used in X-ray detector plates. U.S. Pat. No. 5,892,227, (M. Schieber, et al.) incorporated herein by reference, describes methods for producing such plates from wide-band gap semiconductors by either direct evaporation of Hgl₂ and Pbl₂, or in the case of Hgl₂, by mixing the condensed iodide grains with a binder to form “composite imagers”. After deposition of the polycrystalline grains, the semiconductor is sintered to form a single, coherent, polycrystalline, continuous film.

Up until now, the signal intensities obtained when converting x-rays to electrical signals are poorer for wide band gap semiconductor composite imagers than for physical vapor deposition (PVD) imagers of the same semiconductor. In some cases, the difference in electrical signals between composite and PVD imagers is almost two orders of magnitudes. Additionally, the equipment required to produce PVD imagers is large and costly. Furthermore, the substrates used with PVD coated detectors generally are required to be flat, even though for certain uses, such as non-destructive testing, curved substrates would be more desirable.

A review of prior art polycrystalline Hgl₂ can be found in the following publications.
R. Turchefta, et al., VLSI Readout for Imaging with Polycrvstalline Mercuric Iodide Detectors, Proceedings of the SPIE Conf., San Diego Calif., July 1998, edited by O. H. W. Siegmunds and M. A. Gummin, Vol. 3445, (1998) 356-363.
R. Turchetta, et al., Imaging with Polycrystalline Mercuric Iodide Detectors using VLSI Readout, Proceedings of the Detector Workshop held at XIIth Int. Conf. Cryst. Growth, Jerusalem, Israel, July 1998, edited by R. B. James, L. Franks, P., Nucl. Inst. and Meth. A Vol. 428 (1999) 88
M. Schieber, et al, High flux X-ray response of composite mercuric iodide detectors, Hard Radiation SPIE, Denver, 1999, Vol. 3768 (1999) 296-309.
M. Schieber, et al., Polycrystalline mercuric iodide detectors, Medical Imaging Proc., SPIE, Denver, 1999, Vol. 3770 (1999) 146-155.
M. Schieber, et al. Polycrystalline mercuric iodide detectors, Medical Imaging Proc., SPIE, Denver, 1999, Vol. 3770 (1999) 146-155.
R. Street, et al., High Resolution. Direct detection X-Ray Imagers, Proceedings of SPIE Vol. 3977 (2000) 418.
M Schieber, et al., Radiological X-ray Response of Polycrystalline Mercuric Iodide Detectors, Proceedings of the SPIE Medical Imaging 2000 San Diego, Vol. 3977 (2000) 48.
M. Schieber et al., Mercuric Iodide Thick Films for Radiological X-ray Detectors, Proceedings of the SPIE in Penetrating radiation, Vol 4142 (2000) 197.
M. Schieber et al., Thick Films of X-ray Polycrystalline Mercuric Iodide Detectors, published in JCG (8-2000)

A review of prior art polycrystalline lead iodide detectors can be found in the following publications and in the aforementioned patent.
R. Street, et al., High Resolution. Direct Detection X-Ray Imagers, Proceedings of SPIE Vol. 3977 (2000) 418.
R. Street, et al., X-ray Imaging using Lead Iodide as a Semiconductor Detector, Proceedings of SPIE, Vol. 3659 (1999), p. 36.
R. Street, et al., Large Area X-Ray Image Sensing Using a Pbl2 Photoconductor, Proceedings of SPIE Vol. 3336 (1998) 24.

The films or crystals of lead iodide described in the above references were all prepared using vacuum sublimation, vacuum evaporation or other physical vapor deposition procedures.

### SUMMARY OF THE INVENTION

The present invention is directed toward producing wide band gap semiconductor particle-in-binder (PIB) composite detectors for X-ray digital imagers. The semiconductors discussed herein include, inter alia, Pbl2, Bil3, TIBr, Cd—Zn—Te (CZT) and Hgl2. The compositions, detectors and imaging systems prepared according to the present invention allow for better direct X-ray radiation-to-electrical signal conversion than prior art imagers. They also allow for the fabrication of detector plates and imagers with sensitivities close to the order of magnitude obtained by polycrystalline detector plates and imagers produced by PVD type processes. The materials and systems described herein permit the fabrication of low cost, large area imagers with high sensitivity.

It should be noted that with respect to what is described herein as radiation detector plates, constructions other than planar constructions are contemplated. Therefore these radiation detector plates have at times been more generically described as radiation detection systems. These terms are to be construed as equivalent, both including planar and non-planar constructions. Similarly in what has been described herein, the terms particle, particulate and grain have been used interchangeably and should be deemed to be equivalents. In a like manner, particle size, particulate size and grain size are all deemed to be equivalents.

In one aspect of the present invention, an imaging composition for radiation detection systems is described which comprises an admixture of one or more non-heat treated and non-ground particulate semiconductors with a polymeric binder. Ninety percent of the semiconductor particles have a grain size less than 100 microns in their largest dimension. Typically, the non-heat treated, and non-ground particulate semiconductor Is selected from a group consisting of mercuric iodide, lead iodide, bismuth iodide, thallium bromide and cadmium-zinc-telluride (CZT).

In another aspect of the present invention a radiation detector plate is described which includes at least one substrate which serves as a bottom electrode. It also includes at least one composition layer prepared from an imaging composition which comprises an admixture of at least one non-heat treated, non-ground particulate semiconductor with a polymeric binder. At least ninety percent of the semiconductor particles in the detector plates have a grain size of less than 100 microns In their largest dimension. Typically, the semiconductor is chosen from a group consisting of bismuth iodide, lead iodide, mercuric iodide, thallium bromide and cadmium-zinc-telluride (CZT). The detector plate further includes an upper electrode which is in electrical connection with the composition layer and which is also connected to a high voltage bias.

In a further aspect of the present invention, an image receptor for an imaging system is described. The receptor comprises at least one composition layer comprised as defined in the above described detector plate. The composition layer is positioned on a conductive substrate layer, which forms a bottom electrode. The composition layer is covered by an upper conductive layer, which forms an upper electrode. At least one of the conductive layers is provided with a plurality of conductive areas separated from each other by a plurality of non-conductive areas. A multiplicity of the conductive areas are individually connected, via a charge-sensitive pre-amplifier, to an imaging electronic system.

Finally, in another aspect of the present invention, a method for preparing radiation detector plates is described.

There is thus provided in accordance with the present invention, an imaging composition for radiation detection systems which comprises an admixture of one or more non-heat treated, and non-ground particulate semiconductor with a polymeric binder, wherein at least 90% of the semiconductor particles have a grain size less than 100 microns in their largest dimension. The non-heat treated, and non-ground particulate semiconductor is selected from a group consisting of mercuric iodide, lead iodide, bismuth iodide, thallium bromide and cadmium-zinc-telluride (CZT).

In a preferred embodiment of the invention, the imaging composition possesses at least one of the following features:
the polymeric binder is an organic polymeric binder;
at least 90% of the semiconductor particles has a grain size of less than 15 microns in their largest dimension;
the composition further comprises at least one organic solvent;
the weight ratio of the semiconductor particulates to the binder is from about 4.4:1 to about 26.0:1.

In another embodiment of the present invention, the imaging composition possesses at least one of the following features:
the organic polymeric binder comprises at least one polymer selected from a group consisting of polystyrene, polyurethane, alkyd polymers, cellulose polymers, and acrylic and vinyl polymers and co-polymers and mixtures thereof;
at least 90% of the semiconductor particles have a grain size of less than 10 microns in their largest dimension;
the at least one organic solvent is selected from aliphatic alcohols, ethers, esters, ketones and aromatic and heterocyclic solvents;
the weight ratio of the semiconductor particulates to the binder is from about 6.6:1 to about 19.8:1.

In yet another embodiment, the imaging composition possesses at least one of the following features:
the organic polymeric binder comprises one or more polymer selected from polystyrene, polyurethane, and acrylic and vinyl homo- and co-polymers and mixtures thereof;
at least 90% of the semiconductor particles has a grain size of less than 5 microns in their largest dimension;
the at least one organic solvent is selected from aliphatic alcohols, ethers, esters, ketones and aromatic and heterocyclic solvents;
the weight ratio of the semiconductor particulates to the binder is from about 9:1 to about 15.4:1.

In a further embodiment of the invention, the semiconductor particulates of the imaging composition are precipitated from a solution. The solution has a solvent which is chosen from a group consisting of water, a non-aqueous solvent, a mixed aqueous-non-aqueous solvent and a mixed non-aqueous solvent.

Additionally there is provided in accordance with the present invention a radiation detector plate. The plate includes at least one substrate, which serves as an electrode. The detector plate further includes at least one imaging composition layer prepared from an imaging composition. The composition comprises an admixture of at least one non-heat treated, non-ground particulate semiconductor with a polymeric binder, with at least 90% of the semiconductor particles having a grain size of less than 100 microns in their largest dimension. The semiconductor is typically chosen from a group consisting of bismuth iodide, lead iodide, mercuric iodide, thallium bromide and cadmium-zinc-telluride (CZT). The composite layer is applied onto the substrate. The detector plate also includes a second electrode, which is in electrical connection with the composition layer and with a high voltage bias.

In a further embodiment of the present invention, the radiation detector plate additionally comprises at least one composition layer comprising non-heat treated, non-ground particulate mercuric iodide in admixture with a polymeric binder.

In another embodiment of the radiation detector plate, the at least one composition layer of the radiation detector plate comprises at least two semiconductors selected from a group consisting of bismuth iodide, lead iodide, mercuric iodide, thallium bromide and cadmium-zinc-telluride (CZT).

Additionally, in an embodiment of the radiation detector plate, the at least one composition layer comprises at least two discrete composition layers, each of the discrete layers comprised of at least one semiconductor selected from a group consisting of bismuth iodide, lead iodide, mercuric iodide, thallium bromide and cadmium-zinc-telluride (CZT).

In another embodiment, the detector plate further includes an adhesive layer between the discrete composition layers.

In a preferred embodiment of the radiation detector plate, the at least two discrete composition layers comprise at least one discrete composition layer where the semiconductor is non-heat treated, non-ground particulate lead iodide and at least one discrete composition layer where the semiconductor is non-heat treated, non-ground particulate mercuric iodide.

In another embodiment, the detector plate further includes an adhesive tie layer applied to the substrate, the adhesive chosen from a group consisting of polyacrylics, polyvinyls, polyurethanes, polyimides, cyanoacrylics, silanes, polyesters, and neoprene rubbers and mixtures thereof.

In one embodiment the of the detector plate, the tie layer is a polyacrylic-polyvinyl mixture, while in another embodiment the tie layer is a silane.

In a further embodiment of the detector plate, the substrate is coated with a uniform thin film of electrically conducting material selected from palladium, gold, platinum, indium-tin oxide and germanium.

In yet another embodiment of the detector plate, the second electrode includes a uniform thin film of electrically conducting material selected from carbon, palladium, gold, platinum, indium-tin oxide and germanium. The second electrode can be applied by spraying, painting, sputtering and evaporation.

In yet another embodiment of the detector plate, the one or more substrates is chosen from a group consisting of thin film transistor (TFT) flat panel array, a charge coupled device (CCD), complementary metal oxide semiconductor (CMOS) array and an application specific integrated circuit (ASIC).

In a preferred embodiment of the radiation detector plate according to the present invention, the at least one composition layer possesses at least one of the following features:
the polymeric binder is an organic binder;
at least 90% of the semiconductor particles have a grain size of less than 15 microns in their largest dimension.

In yet another embodiment of the radiation detector plate, the at least one composition layer possesses at least one of the following features:
the organic polymeric binder comprises one or more polymers selected from polystyrene, polyurethane, alkyd polymers, cellulose polymers, and acrylic and vinyl homo- and co-polymers and mixtures thereof;
at least 90% of the semiconductor particles have a grain size of less than 10 microns in their largest dimension.

In another embodiment of the radiation detector plate, the at least one composition layer possesses at least one of the following features:
the organic polymeric binder comprises at least one polymer selected from polystyrene, polyurethane, and acrylic and vinyl homo- and co-polymers and mixtures thereof;
at least 90% of the semiconductor particles have a grain size of less than 5 microns in their largest dimension.

Additionally, in an embodiment of the invention, the one or more composition layers of the detector plate is prepared at room temperature. In a further embodiment, the one or more composition layers of the detector plate is prepared at temperatures below 60° C.

In an embodiment of the invention, the at least one composition layer of the detector plate has a thickness of 40-3000 microns. In another embodiment of the detector plate, the plate can detect radiation in the 6 keV to 15 MeV range.

In another aspect of the present invention, there is also provided an image receptor for an imaging system. The receptor comprises at least one composition layer comprised of an imaging composition as described above. The composition layer is positioned on a conductive substrate layer, the substrate layer forming a bottom electrode. The composition layer is covered by an upper conductive layer, which forms an upper electrode. At least one of the conductive layers is provided with a plurality of conductive areas separated from each other by a plurality of non-conductive areas. A multiplicity of the conductive areas are individually connected, via a charge-sensitive pre-amplifier, to an imaging electronic system.

In a preferred embodiment of the image receptor, the receptor is further characterized by at least one of the following features:
the conductive areas are separated from each other by a dielectric material;
the conductive substrate layer is covered with a uniform, thin film electrode layer selected from the group consisting of palladium, gold, platinum, indium-tin oxide (ITO) and germanium;
the image receptor is adapted for use in an imaging system selected from X-ray and gamma ray imaging systems;
in the at least one composition layer, the polymeric binder is an organic binder;
in the at least one composition layer, at least 90% of the semiconductor particles have a grain size of less than 15 microns in their largest dimension;
an adhesive tie layer between the composition layer and the bottom electrode, the tie layer chosen from a group consisting of polyacrylics, polyvinyls, polyurethanes, polyimides, cyanoacrylics, silanes, polyesters, and neoprene rubbers and mixtures thereof to bind the composition layer to the electrode.

In another embodiment of the image receptor, the at least one composition layer possesses at least one of the following features:
the organic polymeric binder comprises at least one polymer selected from polystyrene, polyurethane, alkyd polymers, cellulose polymers, and acrylic and vinyl homo- and co-polymers or mixtures thereof;
at least 90% of the semiconductor particles have a grain size of less than 10 microns in their largest dimension.

In another embodiment of the image receptor, the at least one composition layer possesses at least one of the following features:
the organic polymeric binder comprises at least one polymer selected from polystyrene, polyurethane, alkyd polymers, cellulose polymers, and acrylic and vinyl homo- and co-polymers or mixtures thereof;
at least 90% of the semiconductor particles have a grain size of less than 5 microns in their largest dimension.

In a further embodiment of the image receptor, the receptor comprises additionally at least one composition layer comprising non-heat treated, non-ground particulate mercuric iodide in admixture with an organic polymeric binder.

In yet another embodiment of the image receptor, the at least one composition layer comprises at least two semiconductors selected from a group consisting of bismuth iodide, lead iodide, mercuric iodide, thallium bromide and cadmium-zinc-telluride (CZT).

In a further embodiment of the image receptor, the at least one composition layer comprises at least two discrete composition layers, each of the discrete layers comprised of at least one semiconductor selected from a group consisting of bismuth iodide, lead iodide, mercuric iodide, thallium bromide and cadmium-zinc-telluride (CZT).

Additionally, in another preferred embodiment of the image receptor the at least two discrete composition layers comprise at least one discrete composition layer where the semiconductor is non-heat treated, non-ground particulate lead iodide and at least one discrete composition layer where the semiconductor is non-heat treated, non-ground particulate mercuric iodide.

In yet another embodiment of the present invention, the image receptor further comprises an adhesive layer between the two discrete composition layers.

In yet another embodiment of the image receptor, the substrate is chosen from a group consisting of a thin film transistor (TFT) flat panel array, a charge coupled device (CCD), a complementary metal oxide semiconductor (CMOS) array and an application specific integrated circuit (ASIC).

In another embodiment of the receptor, the receptor is prepared at room temperature. In yet another embodiment of the receptor, the receptor is prepared at temperatures below 60° C.

In another embodiment of the image receptor, the receptor can detect radiation in the 6 keV to 15 MeV range.

Additionally, there is provided in accordance with the present invention a method for preparing a radiation detector plate, the method Including the steps of:
providing a substrate;
placing a semiconductor imaging composition onto the substrate, thereby forming a composition layer;
applying an electrode to the composition layer on the side distal from the substrate; and
connecting a high voltage bias connection to the electrode.

In an embodiment of the invention, the above method for preparing a radiation detector plate further comprises the step of applying an adhesive tie layer to the substrate prior to the placing step.

In an another embodiment of the method for preparing a radiation detector plate, the placing step further comprises a step of die pressing the composition to form the composition layer. In other embodiments of the method, the placing step further comprises a step of slot die coating the composition to form the composition layer; the placing step further comprises a step of spreading the composition with a doctor blade to form the composition layer; the placing step further comprises a step of spreading the composition with a Mayer rod to form the composition layer; the placing step further includes the step of screen printing the composition to form the composition layer.

In yet another embodiment of the method, the placing step includes a series of placing steps each of the steps forming another composition layer.

Finally in another embodiment of the method, the method further comprises the step of depositing an electrically conductive material on the substrate before the placing step.

These and other objects, features, advantages and embodiments of the present invention will become apparent in light of the detailed description of the embodiments thereof, as illustrated in the accompanying drawings.

### BRIEF DESCRIPTION OF THE DRAWINGS

The present invention will be understood and appreciated more fully from the following detailed description taken in conjunction with the drawings in which:

FIG. 1 is a schematic representation of the layers in a wide band gap semiconductor PIB composite detector prepared according to an embodiment of the present invention;

FIG. 2 is a schematic illustration of a pixel equivalent circuit for photoconductor imagers according to prior art;

FIG. 3 is a schematic illustration of the die press used to form the semiconductor PIB composite detector prepared according to an embodiment of the present invention;

FIG. 4 is a schematic illustration of the doctor blade assembly used to form the semiconductor PIB composite detector prepared according to an embodiment of the present invention;

FIG. 5 is a schematic illustration of top and side views, respectively, the screen printing apparatus used to form the semiconductor PIB composite detector prepared according to an embodiment of the present invention;

FIG. 6 is a graph comparing the sensitivities of a prior art PVD produced Hgl₂ detector and a composite detector prepared according to an embodiment of the present invention;

FIG. 7 is a graph comparing the sensitivities of a prior art composite detector plate and a composite detector plate prepared according to an embodiment of the present invention;

FIG. 8 is a graph showing sensitivity of mercuric iodide-binder composite detectors having different grain sizes prepared according to embodiments of the present invention;

FIG. 9 is a graph showing the sensitivity at different radiation doses of detectors having different grain sizes prepared according to embodiments of the present invention;

FIG. 10 is a graph showing the sensitivity of detector plates made from ground and non-ground mercuric iodide particles prepared according to embodiments of the present invention;

FIG. 11 is a graph showing the effect on signal-to-noise ratio of heat treatment on Hgl₂-binder composite detectors prepared according to embodiments of the present invention;

FIG. 12 is a graph comparing the sensitivity of a PVD produced Hgl₂ detector and various PIB composite detectors prepared according to an embodiment of the present invention;

FIG. 13 is a graph comparing the sensitivities of PVD mercuric iodide, PVD lead iodide, screen printed mercuric iodide and screen printed lead iodide detectors;

FIG. 14 is a schematic diagram of a hybrid bi-layer detector constructed according to a preferred embodiment of the present invention; and

FIG. 15 is a graph showing the bi-polarity of a Hgl₂/Pbl₂/substrate hybrid composite detector constructed according to the present invention.

In the drawings, similar parts have been given similar numbers throughout.

### DETAILED DESCRIPTION OF PREFERRED EMBODIMENTS

The present invention is directed towards producing wide band gap semiconductor-binder composite detectors—herein also called particle-in-binder (PIB) detectors—for use in X-ray digital imagers. The composites, detectors and imaging systems and methods of preparation thereof, as described herein, allow for much better direct X-ray—electrical charge conversion than those of the prior art, thereby producing the first usable digital composite imagers employing the materials discussed herein. The materials and systems described herein permit low cost fabrication of large area composite imagers. The composite can be applied to substrates by any of several methods known in the art, including screen printing (SP), die pressing, doctor blade, slot coater and Mayer rod.

The direct synthesis of the semiconductor particles by precipitation, according to one aspect of the present invention, as described hereinafter produces smaller grain sizes than does the vapor deposition process of prior art methods. Furthermore, the method does not require grinding of the resultant crystals to reduce grain size, thereby preventing morphological deterioration or undesirable phase transformations. The absence of any heat treatment, annealing and/or sintering, allows for easy, low-cost, rapid processing.

Wide band gap semiconductors discussed herein include inter alia Hgl₂, Pbl₂, Bil₃, TIBr and CZT (cadmium-zinc-telluride). Surprisingly, these semiconductors, when prepared and introduced as PIB composites in detectors for use in X-ray imagers in accordance with the present invention, provide much improved signal sensitivity. This is particularly true of Pbl₂. The difference in sensitivity between Pb and Hg PVD detectors is about one order of magnitude, while the difference in sensitivity between mercury and lead PIB composite detectors is less than an order of magnitude. Also surprisingly, these semiconductor PIB composites when applied as base layers in Hgl₂ PIB composite detectors can extend detector lifetimes.

It should be noted that with respect to what is described herein as radiation detector plates, other than planar constructions are contemplated. Therefore these radiation detection plates have at times been more generically described as radiation detection systems. These terms are to be construed as equivalent, both including planar and non-planar constructions.

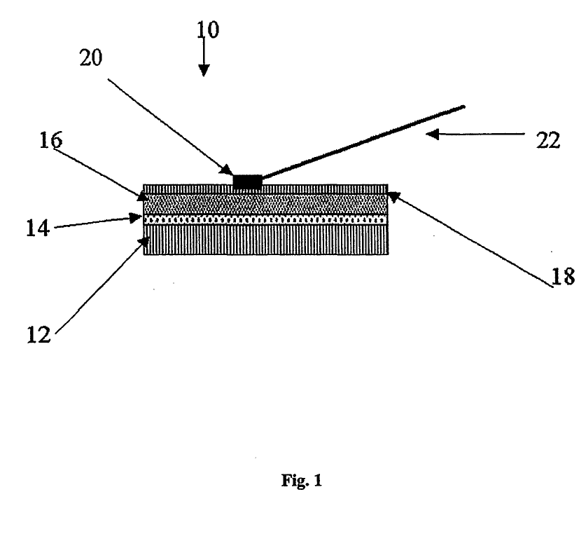

Reference is now made to FIG. 1 where a photo-conducting detector plate 10 for an X-ray imaging system is shown, wherein the detector plate 10 is made from a wide band gap semiconductor PIB composite produced according to the present invention. Detector plate 10 consists of a thin film transistor (TFT) substrate 12 having metallic pixels (not shown), the latter functioning as the bottom electrodes of detector 10. Often these bottom electrodes are formed from indium-tin oxide (ITO). The bottom pixel electrodes are often coated with a tie layer 14, such as Humiseal® 1B12 (a polyacrylic, polyvinyl mixture dissolved in a mixed methyl ethyl ketone/toluene solvent), a polyimide or a silane. Tie layer 14 acts as an adhesive that prevents a semiconductor PIB composite 16 from peeling off the bottom pixel electrodes. Tie layer 14 is usually less than 0.5 micron thick, and is generally applied by dipping the substrate into a dilute solution of the adhesive, from which the solvent is subsequently allowed to evaporate. Alternatively, tie layer 14 can be painted onto the upper surface of the bottom pixel electrodes or spin coated onto the substrate.

A layer consisting of semiconductor PIB composite 16 can be applied directly onto adhesive coated substrate 12 by any of the methods described herein below. These methods include, but are not limited to, use of a doctor blade, Mayer rod, slot coater, die press or screen printing (SP). A vacuum deposited, painted or sprayed continuous upper electrode 18 covers the semiconductor PIB composite layer 16 on the side distal from substrate 12. A high voltage platinum bias wire 22 is attached to upper electrode 18 using a conductive glue 20. The latter can be chosen from any of several commercially available glues. Optionally, the complete detector plate 10 can be mechanically encapsulated with Parylene, Humiseal® 1B12, or some other such insulating, inert material (not shown in FIG. 1), and connected to a pixel array imager readout electronics unit. The readout electronics unit is connected to a PC and the images acquired can be evaluated with image viewing and acquisition software.

Semiconductor PIB composite layer 16 acts as a photoconducting semiconductor in room temperature X-ray radiation detector 10 of FIG. 1. Substrate 12 of FIG. 1 is generally either a pixel readout flat panel (FP), charge coupled device (CCD), complementary metal oxide semiconductor (CMOS) array or application specific integrated circuit (ASIC). These substrates are commercially available, and may be connected to readout units such as the one mentioned above.

Typical FP and CCD substrates used for detector 10 of FIG. 1 contain square pixels having a conductive coating, the latter serving as the bottom pixel electrodes for the detector. The pixels are typically about 100×100 microns, and each pixel is separated from its nearest neighbors in all directions by about 10-15 microns.

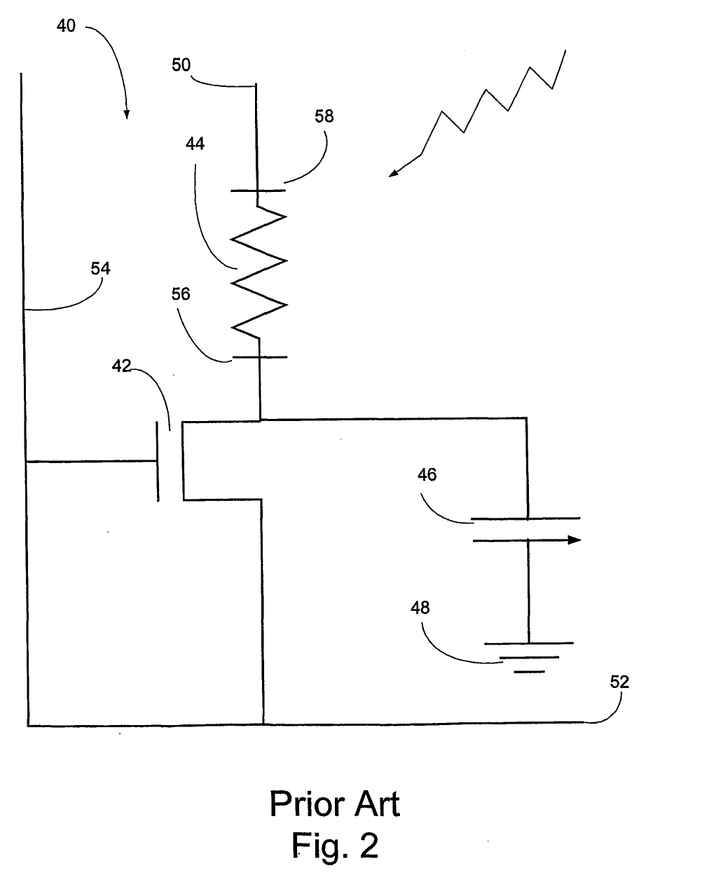

Reference is now made to FIG. 2 which illustrates a typical prior art pixel equivalent circuit 40 for a photoconducter detector 44 plate in an X-ray imaging system. Circuit 40 shows one detector electrode 58 connected to a bias voltage 50. The second electrode 56 is connected to a storage capacitor 46 and an a-Si:H (amorphous silicon) switching thin-film transistor (TFT) 42. Storage capacitor 46 is connected to a ground plane 48. Thin-film transistor 42 is connected to both a gate line 54 and a data line 52, with data being fed to a readout unit (not shown) through data line 52. Except for the contact between the second electrode 56 of detector 44 to TFT 42, the rest of the pixel is isolated from the detector's 44 electrodes 58 and 56 by an insulation layer.

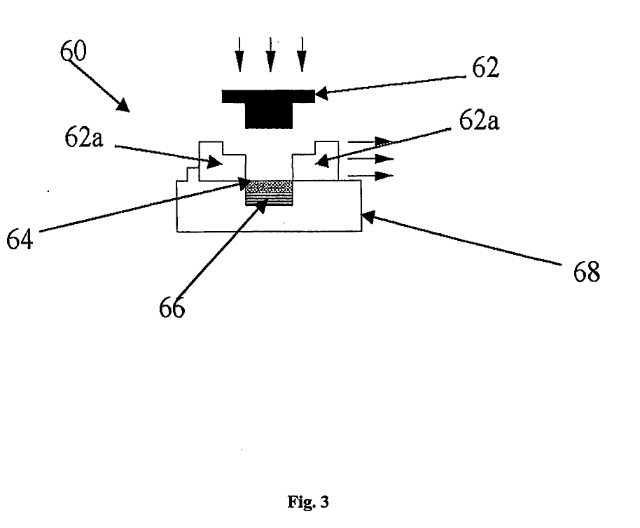

Reference is now made to FIGS. 3-5 where three coating methods are shown which can be used to apply the wide band gap semiconductor PIB composites of the present invention to substrates. These three coating methods are exemplary only and should not be considered limiting with respect to other coating methods which also could be used.

FIG. 3 shows a die press 60 that may be used to prepare detectors from the composite photoconductor material taught in the present invention. The pressing operation is effected at room temperature at relatively low pressures 40-100 g/cm², preferably about 50 g/cm². Die press 60 can be vibrated before or during pressing to reduce undesirable voids in the composite layer 64 of the detector.

FIG. 3 shows a mold 68 containing an adhesive-coated substrate 66 on which a wide band gap semiconductor PIB composite 64 is placed. Composite 64 is quickly pressed at room temperature with punch 62, after which punch 62 and die holder 62A are displaced laterally along the top of mold 68 leaving a substantially level composite surface. The detector layers 64 and 66 can be left to dry at room temperature in mold 68 or more preferably dried after removal from mold 68.

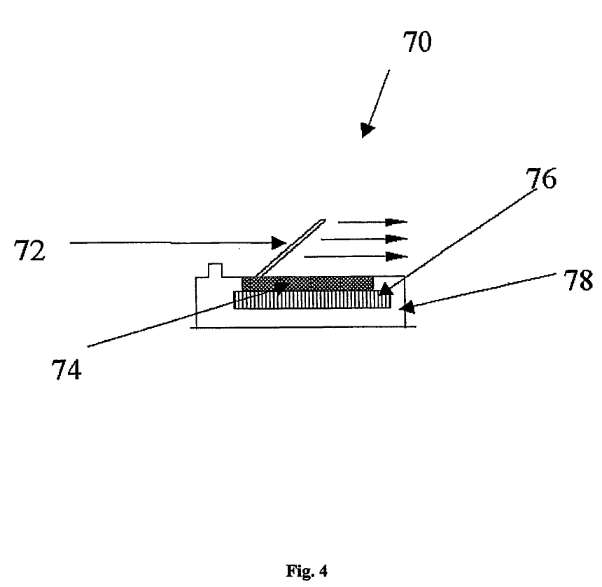

FIG. 4, to which reference is now made, shows a doctor blade assembly 70 used to form the composite layer in the detector of the present invention. Mold 78 contains an adhesive coated substrate-76 upon which a wide band gap semiconductor PIB composite 74 prepared according to the present invention is deposited. A doctor blade 72 then moves laterally across the face of mold 78, removing excess material, resulting in a substantially level top surface of the composite. The detector 74 and 76 is then removed from mold 78 and allowed to dry at room temperature. When using the die press of FIG. 3 or doctor blade assembly of FIG. 4, the final thickness of the detector is controlled by using spacers having appropriate thickness.

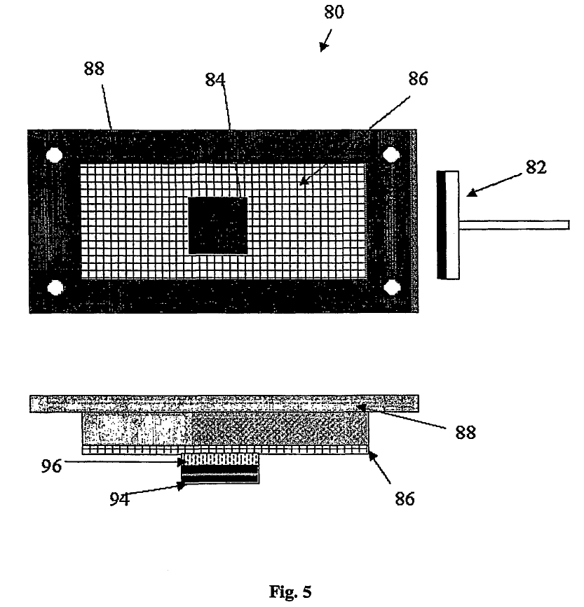

Reference is now made to FIG. 5, which shows top and side views of a screen print assembly 80 which can be used to produce detectors from the composite material taught in the present disclosure. The composite is applied in layers, each layer usually being about 40 microns thick. The thickness of each layer is generally determined by the thickness of the mesh 84. The total thickness of the composite layer in the detector can reach 3 mm or more which is adequate for use with X-rays having energies in the range up to several tens of MeV. Currently, the size of the plates can be 17″×17″, which is the current state of the art for pixilated substrates; however, there is no intrinsic limitation to producing significantly larger plates. There is also no intrinsic limitation to fabricating plates having thicknesses which can be used with radiation on the order of GEVs.

FIG. 5 shows uncoated 84 and resin coated 86 meshes both housed in an aluminum frame 88. A leveling element, here a squeegee 82, moves across the surface of meshes 84 and 86. An adhesive coated substrate 94, often a Humiseal® 1B12 coated substrate is placed below mesh 84 and 86 and the mercuric-iodide binder composite is spread over the screen and squeegeed through the mesh. The squeegeed composite forms a relatively level layer 96. The substrate 94 can be repeatedly lowered so that successive layers of the composite can be added. Typically, the layers are on the order of 40 microns with the number of layers applied determining the total thickness of detector 94 and 96.

The adhesive tie layer described herein above in conjunction with FIGS. 1, 3, 4 and 5 is in fact an optional layer, needed only when the binder in the composite can not adhere directly to the bottom electrode. In cases where the binder adheres directly to the electrode, an adhesive tie layer is not needed. The tie layer therefore is not obligatory in all embodiments and should be construed as such throughout the discussion herein.

The detector plates produced by any of the three methods described above is dried, generally at room temperature. It can be dried at somewhat higher temperatures, but never at temperatures in excess of 60° C.

After drying, a continuous upper electrode such as gold or a carbon based contact is deposited. The upper electrode can be deposited using any of a number of methods including vacuum deposition, sputtering, painting or spraying. Gold electrodes are preferably applied via sputtering. Carbon electrodes are generally applied by painting or spraying a carbonaceous dispersion that forms a substantially continuous electrode layer when dry. If desired, a metal layer can be further deposited on the carbon layer to increase electrical conductivity. Other electrode materials that do not react with wide band gap semiconductor materials, such as those enumerated below, also can be used to form a continuous upper electrode. They can be applied by the methods described herein above.

A high voltage platinum wire is then attached to the continuous upper electrode by means of any of a number of commercially available conducting glues. Particularly preferable are conducting carbon based adhesives. The platinum, wire serves as a high voltage bias connector that can be connected to the readout electronics. Images are obtained from the readout electronics and displayed. Details of the readout electronics receiving the digital data generated by the detector has been described elsewhere, for example in the publication of Street et al., Proc. SPIE Vol 3977 (2000), 418, cited above.

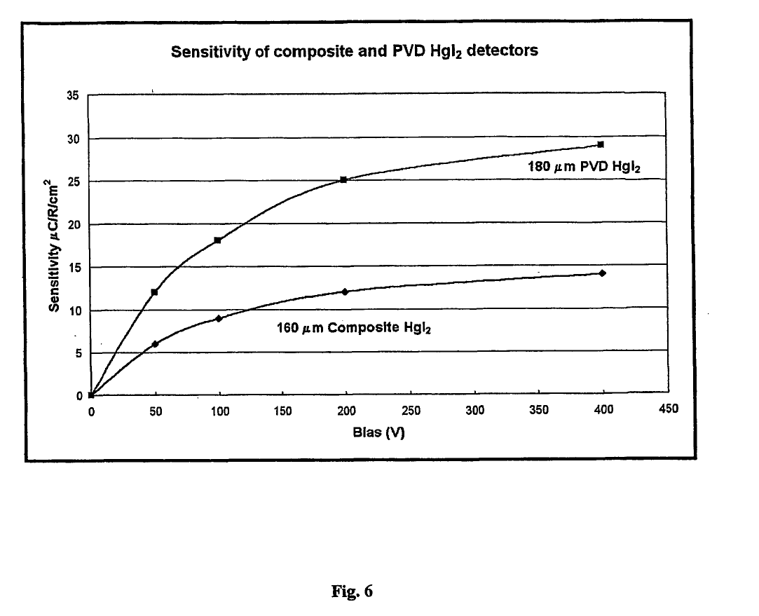

The present invention inter alia provides for a Hgl₂—binder composite detector plate which can attain about 40-50% of the sensitivity obtained by non-composite polycrystalline Hgl₂—PVD produced imagers. Referring to FIG. 6, the heightened sensitivity of Hgl₂—binder composite detectors prepared according to the present invention is readily seen. The improved direct conversion of X-rays to electrical charges in composite imagers which use materials of the present invention produces good quality digital images. Furthermore, the ease of fabrication, their low cost, and the increase in safety of these composite imagers make them more desirable than PVD fabricated imagers.

It has been found that the direct precipitation of the starting material, mercuric iodide, from aqueous solution is important in preparing high-quality mercuric iodide-binder composite detectors. This method ensures small grain size, something that prior art preparation methods, such as repeated evaporation and sublimation, are unable to do. The size of repeatedly sublimed mercuric iodide grains is usually 50-300 microns; grinding is required to obtain smaller grain sizes. Grinding however harms the morphology of the resulting grains because it induces plastic deformations. These deformations may act as electron traps, interfering with the sensitivity of the composite detector plates made with such ground grains.

Acceptable results are obtained by precipitating Hgl₂ directly from an aqueous solution, starting with stoichiometrically matched molar solutions of mercuric chloride and potassium iodide e.g. a solution of 0.6 M HgCl₂ and a solution of 1.2 M KI. The starting iodide and chloride should be at least 99%, or more preferably 99.9%, pure, purities readily available commercially. The two reagents are added slowly and the solution mixed vigorously with a mechanical or magnetic stirrer. The precipitated Hgl₂ is washed with water, filtered, and dried. The washing, filtering and drying cycles can be repeated a number of times but no additional purification procedures are needed. The material is then sieved and separated into fractions based on grain size. The preferred fraction for preparing composite detectors is mercuric iodide having grain diameters of 100 microns or less, more preferably 15 microns or less, 10 microns or less, or 5 micron or less.

While the above has discussed precipitation from aqueous solution, this should be considered as exemplary only and not limiting. Similarly, while HgCl₂ and KI are discussed herein, it is readily appreciated that other soluble mercuric and iodide salts can also be used in the synthesis of mercuric iodide. Precipitation of Hgl₂ can be effected from many non-aqueous solvents, or mixed non-aqueous solvent systems or mixed aqueous-non-aqueous solvent systems as well, when mercuric and iodide salts soluble in such solvents are used. Non-aqueous solvents which can be used include for example acetone, methanol, ethanol, dimethyl sulfoxide, and toluene.

The powder obtained is then mixed with a binder, generally an organic binder but other binders such as silicon based binders can be used as well. Binders which can be used include binders chosen from the following classes: acrylic and methacrylic ester polymers, polymerized ester derivatives of acrylic and alpha-acrylic acids, polymerized butyl methacrylates, chlorinated rubber, vinyl polymers and co-polymers such as polyvinyl chloride and polyvinyl acetate, cellulose esters and ethers, alkyd resins and silicones. Mixtures of such resins or mixtures of such resins and conventional plasticizers, such as phthalates, adipates and phosphates, may also be used. Particularly preferable as binders are polystyrene and Humiseal® 1B12, the latter a polyacrylic-polyvinyl blend. In situ polymerization of the binder, for example, styrene, using peroxide catalysts can also be employed.

When polystyrene is used as the binder a colloidal solution of, for example, 25 wt % of the polymer in toluene is prepared. In order to obtain faster dissolution of the polystyrene in toluene, the mixture can be heated gently and then slowly cooled to room temperature. The mercuric iodide powder prepared as described above is then mixed in the weight ratio of Hgl₂ to dried polystyrene of between 4.4:1 and 26.0:1, preferably between 6.6:1 and 19.8:1 and even more preferably 9.0:1 and 15.4:1. Similar ratios can be used with other binders. The material is mixed thoroughly to wet all of the mercuric iodide powder and to obtain a homogenous mixture.

The TFT flat panel arrays or CCD substrate is coated with a less than 0.5 micron tie layer of an adhesive such as Humiseal® 1B12, other polyacrylics, polyvinyls, polyurethanes, polyimides, silanes, cyanoacrylics, polyesters, neoprene rubbers or mixtures thereof. The adhesive is generally applied by dipping the substrate into a dilute solution of the adhesive and evaporating off the solvent. Spin coating of the adhesive onto the substrate can also be used. Alternatively, the adhesive can be painted or sprayed on above the bottom pixel electrodes. After the adhesive is applied, the Hgl₂— binder composite is placed onto the adhesive layer by any of the methods described herein above.

In order to achieve long lifetimes for the imager, both the bottom and top electrodes can be made of indium-tin oxide (ITO), gold, carbon, silicon, germanium, chromium, nickel, platinum or palladium electrodes. These latter materials do not react significantly with mercuric iodide. When a carbon electrode is used a metal layer can be deposited on it to further increase conductivity. It is inadvisable to use titanium-tungsten alloy (Ti—W), In, Al, or Cu because they react with the mercuric iodide composite.

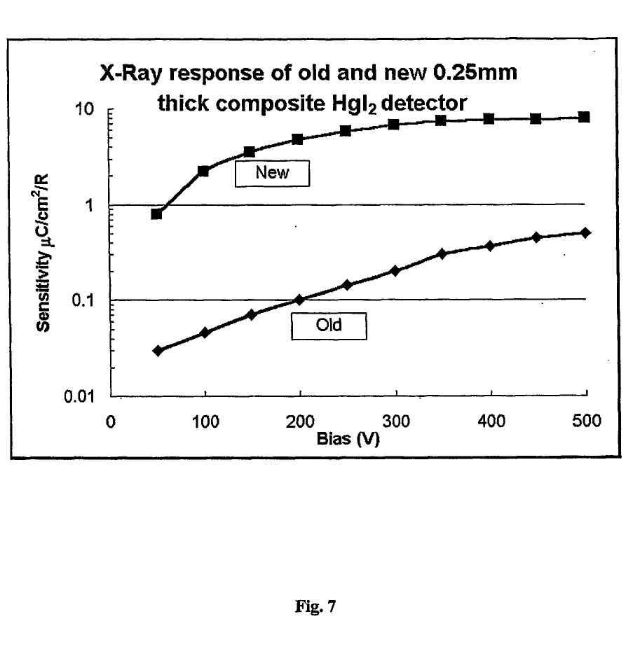

Reference is now made to FIG. 7 where a graph of sensitivity versus bias is shown for detectors made with mercuric iodide composites prepared as described in prior art (U.S. Pat. No. 5,892,227) and the present invention. Detector plates using mercuric iodide-binder composites prepared according to the present invention show sensitivities about 1.5 orders of magnitude greater than plates prepared using composites prepared according to prior art. This may be a result of the small size of the grains used, their non-deformed morphology, or the lack of any heat treatment, or a combination of these factors.

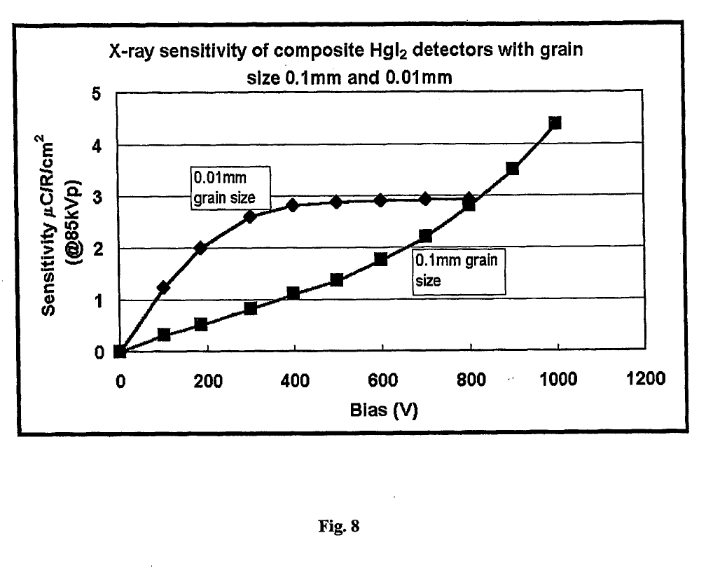

Reference is now made to FIGS. 8-11, which show the effect of grain size, radiation dosage, grinding and heat treatment on sensitivity and signal-to-noise ratio for mercuric iodide composite detectors.

FIG. 8 shows the effect of grain size on sensitivity. Surprisingly, smaller grain size leads to better sensitivity at low operating bias. In view of the fact that single crystal mercuric iodide detectors exhibit higher sensitivities than polycrystalline detectors, it would have been expected that detectors with larger Hgl₂ grains would show higher sensitivities than detectors using smaller Hgl₂ grains. FIG. 8 shows that the opposite is true.

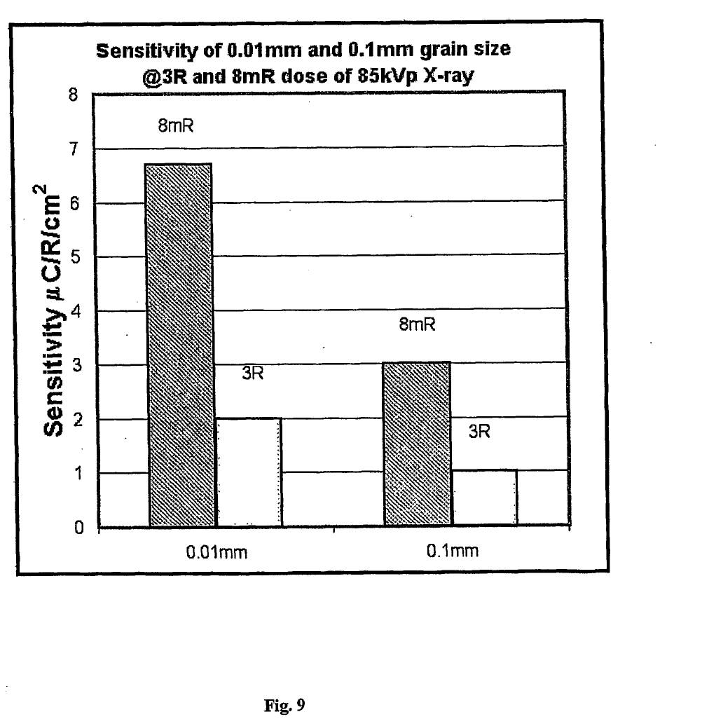

As can also be seen, the performance of the detector made from smaller grains compared to the detector made from larger grains remains substantially unchanged above a certain operating bias, here about 300 V. This indicates that higher biases are not advantageous especially since dark current increases very much more rapidly at higher biases. Importantly, FIG. 9 shows that while smaller particles provide better sensitivity than larger grains, the effect is more pronounced at the lower radiation doses (8 mR) commonly used in medical imaging.

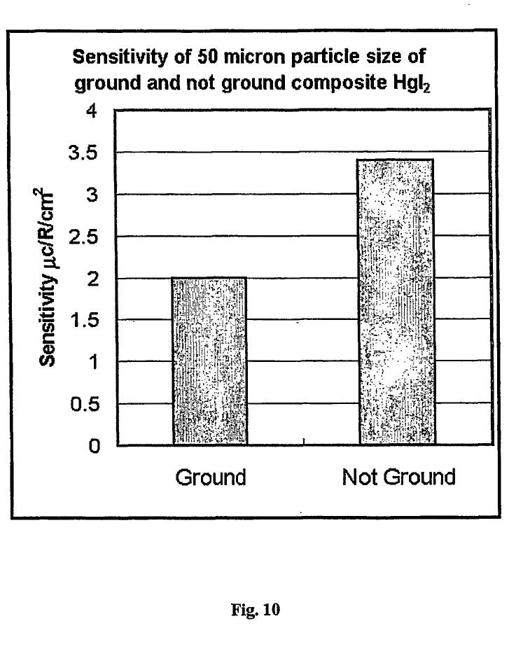

As mentioned above, material synthesized by aqueous precipitation can produce relatively small grains that do not require grinding. Sieving alone is sufficient to produce fractions of particles 90% of which have diameters of 5 microns or less as determined by SEM photographs and microscopic inspection. Prior art detectors using mercuric iodide produced after multiple sublimations do not produce particles of small size without further processing i.e. grinding. Typically, multiple sublimation produces particles in the 50-300 micron range. As shown in FIG. 10, particles that are not ground display higher sensitivities than particles that are ground. It is posited that this is a result of plastic deformations introduced by grinding.

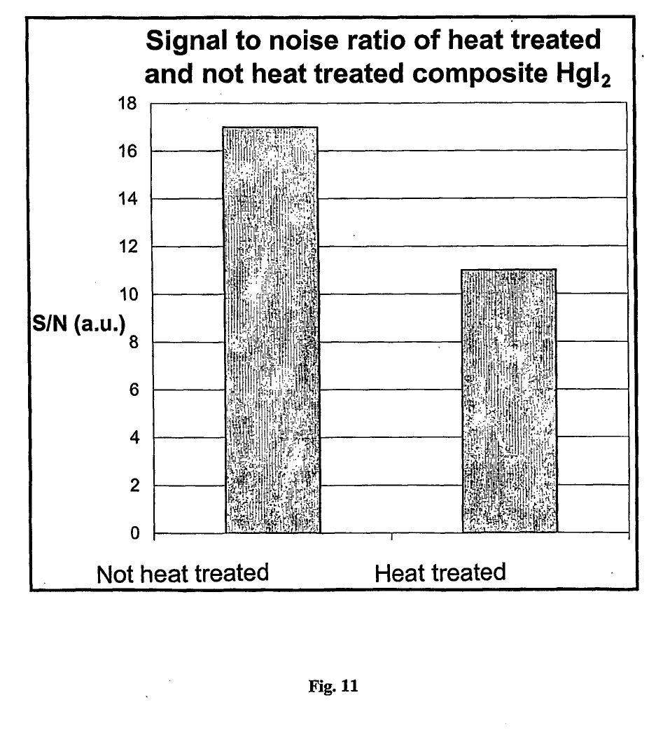

Finally, FIG. 11 shows the effect of heat treatment on the signal to noise (S/N) ratio of composite detectors. The heat-treated detector was heated at 120° C. for 10 minutes under a pressure of 1 kg/cm². FIG. 11 shows that heat treatment degrades the performance of mercuric iodide-binder composites. It should be noted that the use of the term “heat treatment” or “heat treated” herein encompasses inter alia sintering and/or annealing. Thus the Hgl₂ used in the present invention is neither sintered nor annealed, since such operations require heat treatment.

### EXAMPLE 1

A 0.6 M aqueous solution of HgCl2 and a 1.2 M aqueous solution of KI were mixed quickly in a container. The Hgl₂ which precipitated was washed with water, filtered and dried, the washing, filtering and drying cycle being repeated three times. The mixture was then sieved and separated into fractions by grain size. The fraction passing through the 20 micron sieve was used and microscopic inspection of that fraction showed that more than 90% of the particles had a diameter of 5 microns or less. The mercuric iodide particulates were then mixed with a 25 wt % polystyrene/toluene solution. The homogeneous mixture obtained had a weight ratio of Hgl₂ to dry polystyrene of about 4.4:1.

A TFT substrate was coated with indium-tin oxide (ITO) to which a thin adhesive tie layer (Humiseal® 1B12) was applied. The ITO layer served as the bottom pixel electrode. The pixels had a size of about 100×100 microns, each separated by about 10 microns. The adhesive tie layer had a thickness of less than 0.5 micron and was applied by dipping the bottom pixel electrodes of the substrate into a dilute solution of the adhesive after which the solvent was allowed to evaporate.

The TFT substrate was then placed in a die press similar to the one shown in FIG. 3 and the mercuric iodide-polystyrene composite mixture was deposited on top of the Humiseal® tie layer. The detector plate had a final thickness of 150 microns and it had an active area of 2″×2″. The thickness was controlled by placing a spacer having the desired thickness in the die.

The detector plate was then removed from the die and allowed to dry at room temperature. After drying, a continuous upper electrode of gold was applied by vacuum evaporation. A thin Pt wire was attached to the upper continuous electrode using a conductive glue; the Pt wire served as a high voltage bias contact.

### EXAMPLE 2

As in Example 1, but instead of placing the Hgl₂/polystyrene mixture in a die press, the mixture was placed in a doctor blade assembly similar to the one shown in FIG. 4.

### EXAMPLE 3

As in Example 1, but instead of placing the Hgl₂/polystyrene mixture in a die press, the mixture was placed on a screen printing apparatus similar to the one shown in FIG. 5.

### EXAMPLE 4

As in Example 1, but instead of casting the Hgl₂/polystyrene mixture on a TFT substrate array, placed in a die press, the mixture was cast on a CCD pixel array with pixel dimensions similar to that disclosed in Example 1.

### EXAMPLE 5

As in Example 1, but instead of using polystyrene as the binder in the composite, Humiseal, a polyacrylic-polyvinyl polymeric mixture diluted with toluene and methyl ethyl ketone, was used as the binder. The Humiseal®/Hgl₂ ratio was the same as in Example 1 and the detector was cast in a die press.

### EXAMPLE 6

Instead of using vacuum evaporated gold as the continuous upper electrode as in Example 1, magnetron sputtered gold was used as the continuous upper electrode. All other preparation steps were identical to those described in Example 1.

While the present invention has been described herein above in terms of mercuric iodide synthesized by precipitation from solution, the method of preparation discussed and the examples described should be viewed as illustrative only and non-limiting. It is readily appreciated by one skilled in the art that any method of preparing mercuric iodide which results in small grains of the size defined herein which do not require grinding and heat treatment can also be used. For example, the reaction of elemental mercury and iodine can be used to produce Hgl₂ having small grain sizes.

The adhesive tie layer described hereinabove in conjunction with FIGS. 1, 3, 4 and 5 is in fact an optional layer, needed only when the binder in the composite does not adhere directly to the bottom electrode. In cases where the particle-in-binder (PIB) composite adheres directly to the electrode, an adhesive tie layer is not needed. The tie layer, therefore, is not an essential element in every embodiment and should not be construed as such throughout the discussion herein.

In a modification of the compositions, detectors and imaging systems of the present invention, it has been found possible to replace mercuric iodide by one or more particulate iodides or bromides selected from bismuth iodide, lead iodide and bismuth iodide, lead iodide, mercuric and thallium bromide. Small grain size cadmium-zinc-telluride (CZT) can also be used. The preparation of these wide band gap semiconductor particles, compositions, and detectors uses methods, procedures and materials substantially identical to those described above, in conjunction with mercuric iodide particles, compositions, detectors and imaging sytems.

The present invention provides wide band gap semiconductor PIB composite detectors that can attain sensitivities on the order of magnitude of their corresponding polycrystalline PVD produced detectors. For example, as mentioned previously, a Hgl₂ PIB composite detector plate prepared by the present invention can attain about 40-50% of the sensitivity obtained by non-composite polycrystalline Hgl₂—PVD produced imagers. In addition, the PIB composite detectors discussed herein, particularly PIB Pbl₂ composite detectors surprisingly can attain results on the order of magnitude of Hgl₂ PIB composite detectors. This result is surprising in view of the fact that the difference in sensitivity of the two materials in prior art detectors is often two or more orders of magnitude.

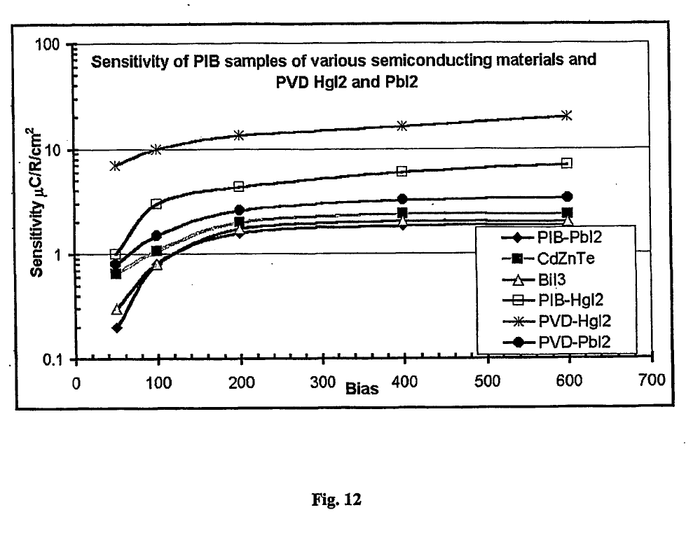

Referring to FIG. 12, the heightened sensitivity of composite detectors prepared according to the present invention is readily seen. The Pbl₂ PIB composite detector shows sensitivities of the same order of magnitude of its sister PVD Pbl₂ detector. At the same time the Pbl₂ PIB composite detector is only less than an order of magnitude lower than that of the mercuric iodide PIB detector. The improved direct conversion of X-rays-to-electrical charges in composite imagers which use materials of the present invention produce usable quality digital images. Furthermore, the ease of fabrication, their low cost, and the increase in safety of these composite imagers make them more desirable than PVD fabricated imagers.

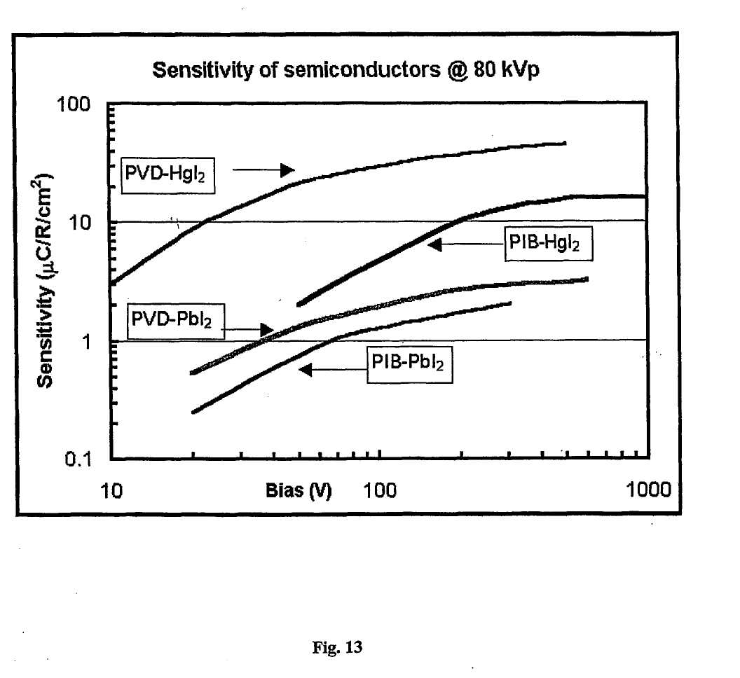

Reference is now made to FIG. 13 where a graph of sensitivity versus bias is shown for mercuric iodide and lead iodide detectors prepared by both the PVD method and the PIB composite method according to the present Invention. Again we see that the lead iodide is well within the usable range, and that even more surprisingly, its sensitivity is of the same order of magnitude as a lead iodide PVD detector.

As with mercuric iodide discussed above, it has been found that the direct precipitation of the starting wide band gap semiconductor material, lead iodide, bismuth iodide, or thallium bromide, from aqueous solution is important in preparing high-quality semiconductor PIB composite detectors. The precipitated particles are not ground ensuring the retention of their crystalline perfection. Direct precipitation ensures small grain size, something that prior art preparation methods, such as repeated sublimation and condensation are unable to achieve. The size of repeatedly sublimed and condensed mercuric or lead iodide grains, for example, is usually 50-300 microns; grinding is required to obtain smaller grain sizes. Grinding however, alters the morphology of the resulting grains and induces plastic deformations. These deformations may act as electron traps, interfering with the sensitivity of the composite detector plates made with such ground grains. Alternatively, or additionally, a phase transformation can occur under the shear stress induced by grinding with the resultant phase being less responsive to photo-conduction.

Smaller grain sizes may be obtained by precipitating Pbl₂ or other semiconductors directly from aqueous solution. Starting with solutions, often stoichiometrically matched molar solutions, of lead nitrate and potassium iodide, e.g. a solution of 0.3 M Pb(NO₃)₂ and a solution of 0.6 M KI, small grain size Pbl₂ is obtained. The starting iodide and nitrate should be at least 99% pure or more preferably 99.9% pure, and such purities are readily available commercially. The two reagents are added slowly and the resulting solution is mixed vigorously using, for example, a mechanical or magnetic stirrer. The solution is then allowed to stand. The precipitated Pbl₂ is washed with water, filtered, and dried. The washing, filtering and drying cycles can be repeated a number of times but no additional purification procedures are needed. In the case of Pbl₂, the precipitate so formed has grains having a platelet structure, which is generally less than 5 microns in its largest dimension. These platelets do not require further fractionation by size. In the case of other semiconductors such as Hgl₂, the dried precipitated material is sieved and separated into fractions based on grain size. The preferred fraction for preparing composite detectors are semiconductor particulates having grain diameters or other largest dimension of 100 microns or less, or more preferably 15 microns or less, 10 microns or less or 5 microns or less.

While the above has discussed precipitation from aqueous solution, this should be considered as exemplary only and not limiting. Similarly, the salts discussed herein as raw materials for the production of small grain semiconductor particles are to be considered as exemplary only and non-limiting. It is readily appreciated that other soluble salts possessing the required cation or anion can also be used. Precipitation of the semiconductor can be effected from many non-aqueous solvents, or mixed non-aqueous solvent systems or mixed aqueous-non-aqueous solvent systems as well, when suitably soluble starting salts are used. Non-aqueous solvents that can alternatively be used include, for example, acetone, methanol, ethanol, dimethyl sulfoxide, and toluene.

The powder obtained is subsequently mixed with a binder, generally an organic binder, but other binders such as silicon based binders can be used as well. Binders which can be used include binders chosen from the following classes: acrylic and methacrylic ester polymers, polymerized ester derivatives of acrylic and alpha-acrylic acids, polymerized butyl methacrylates, chlorinated rubber, vinyl polymers and co-polymers such as polyvinyl chloride and polyvinyl acetate, cellulose esters and ethers, alkyd resins, polymeric urethanes, polymeric styrenes and silicones. Mixtures of such resins or mixtures of such resins and conventional plasticizers, such as phthalates, adipates and phosphates, may also be used. Particularly preferable as binders are polystyrene and Humiseal® 1B12, the latter being a polyacrylic-polyvinyl blend.

When polystyrene is used as the binder, a mixture of, for example, 25 wt % of the polymer in toluene is prepared. In order to obtain faster dissolution of the polystyrene in toluene, the mixture can be heated gently and then slowly cooled to room temperature. The semiconductor powder prepared as described above is then mixed in the weight ratio of semiconductor to dried polystyrene of between 4.4:1 and 26.0:1, preferably between 6.6:1 and 19.8:1 and even more preferably 9.0:1 and 15.4:1. Similar ratios can be used with other binders. The material is mixed thoroughly to wet all of the semiconductor powder and to obtain a homogenous mixture.

The TFT flat panel arrays or CCD substrate may be coated with a thin tie layer of an adhesive such as Humiseal® 1B12, although other polyacrylics, polyvinyls, polyurethanes, polyimides, silanes, cyanoacrylics, polyesters, neoprene rubbers or mixtures thereof may be used instead. The adhesive is generally applied by dipping the substrate into a dilute solution of the adhesive and evaporating off the solvent. Additionally, the adhesive can often be spin coated onto the substrate. Alternatively, the adhesive can be painted or sprayed on above the bottom pixel electrodes. After the adhesive is applied, the semiconductor PIB composite is placed onto the adhesive layer by any of the methods described herein above.

In order to achieve extended lifetimes for the imager, both the bottom and top electrodes are preferably made of indium-tin oxide (ITO), gold, carbon, silicon, germanium, chromium, nickel, platinum or palladium. These materials do not react significantly with wide band gap semiconductors. It is inadvisable to use titanium-tungsten alloy (Ti—W), In, Al, or Cu because these materials can react with some wide band gap semiconductor PIB composites.

### EXAMPLE 7

7.3 g of Pb(NO₃)₂ (Aldrich Chemicals, 99% pure) was added to a beaker containing 800 ml of de-ionized water, while 7.3 g of KI (Acros, 99% pure) was dissolved in a second beaker containing 200 ml of de-ionized water. Both solutions were heated to 100° C. and subsequently mixed together at that temperature. A yellow precipitate, Pbl₂, in the form of thin, crystalline platelets precipitated out of the solution after the solution was cooled to room temperature and left standing for 24 hours. The precipitate was filtered and washed with 500 ml. de-ionized water at room temperature for 10 minutes. After washing, the precipitate was filtered again and left to dry in air for 48 hours at room temperature. Nine grams of yellow, plate-like, Pbl₂, micro-crystals were obtained.

A yellow paste was obtained by taking 5 grams of the above Pbl₂ precipitate and mixing it with about 2.5 ml of 25 wt % polystyrene/toluene solution. A 400 micron thick layer of this paste was screen printed onto an indium-tin oxide (ITO) electrode, the latter covering a glass substrate. Screen printing was effected as described herein above. The Pbl₂ layer was dried for 100 hours in air at room temperature.

Electrodag®, a graphite methyl ethyl ketone based dispersion, was painted onto the lead iodide PIB layer and the solvent allowed to evaporate leaving a continuous carbon electrode. A platinum wire was then attached to the Electrodag® electrode using any one of several commercially available conducting glues. After drying the Electrodag® electrode at room temperature in air for 48 hours, the detector was ready for making measurements.

### EXAMPLE 8

As in Example 7, but instead of screen printing the Pbl₂/polystyrene paste, the paste was applied with a doctor blade assembly similar to the one shown in FIG. 4.

### EXAMPLE 9

As in Example 7, but instead of screen printing the Pbl₂/polystyrene paste, the paste was applied in a die press similar to the one shown in FIG. 3.

### EXAMPLE 10

As in Example 7, but instead of applying the Pbl₂/polystyrene paste onto a glass substrate covered with an ITO electrode, the paste was applied onto a CCD pixel array.

### EXAMPLE 11

As in Example 7, but instead of using polystyrene as the binder in the PIB composite material, Humiseal®, a commercially available polyacrylic-polyvinyl polymeric mixture diluted with toluene and methyl ethyl ketone, was used as the binder. The Humiseal/Pbl₂ ratio was the same as in Example 7 and the detector was pressed in a die press.

### EXAMPLE 12

As in Example 7, but instead of using a continuous carbon upper electrode, a gold electrode was sputtered onto the Pbl₂ PIB composite using a magnetron sputtering machine.

### EXAMPLE 13

150 ml of 70% nitric acid was added to 400 ml of de-ionized water In a beaker, and mixed. 70 grams of BiO(NO₃) (Merck) was added to the diluted nitric acid solution. Twenty grams of KI (Acros 99% pure) was dissolved at room temperature in another beaker, this one containing 100 ml of de-ionized water. The KI solution was then added to 100 ml of the bismuth solution and the resulting mixture was stirred for two minutes at room temperature and allowed to stand. A black precipitate was obtained.

The precipitate was filtered and washed in 400 ml of 7% nitric acid for three hours. After washing, the precipitate was filtered again and dried for 72 hours at room temperature. Twenty grams of the dry, black, slightly agglomerated Bil₃ powder was obtained. The powder agglomerates were easily broken apart with a plastic spoon.

4.5 grams of the black Bil₃ powder was mixed with about 2 ml of 25 wt % polystyrene/toluene solution and a black paste was obtained. The black paste was screen printed as described hereinabove onto an ITO electrode coated on a glass substrate. The layer was dried in air at room temperature for 100 hours.

Electrodag®, a graphite methyl ethyl ketone based dispersion, was coated onto the top of the Bil₃-polystyrene PIB layer to form an electrode layer. After the electrode layer was dried, a platinum wire was connected to the carbon electrode using any one of several commercially available conductive glues. After drying in air at room temperature for 48 hours, the composite detector was ready for use.

### EXAMPLE 14

Equal volumes of a 0.6 M aqueous solution of HgCl₂ and a 1.2 M aqueous solution of KI were mixed quickly in a container and allowed to stand. The Hgl₂, which precipitated out of the solution, was washed with water, filtered and dried, the washing, filtering and drying cycle being repeated three times. The mixture was then sieved, shaken and separated into fractions by grain size. The fraction passing through a 20 micron sieve was used and microscopic inspection of that fraction showed that more than 90% of the particles had a diameter of 5 microns or less. About 10 grams of mercuric iodide particles were then mixed with about 5 ml of 25 wt % polystyrene/toluene solution. The homogeneous mixture obtained had a weight ratio of Hgl₂ to dry polystyrene of about 9:1.

A TFT pixilated substrate was coated with indium-tin oxide (ITO), and a thin adhesive tie layer (Humiseal® 1B12) was applied thereto. The ITO layer served as the bottom pixel electrode. The pixels had a size of about 100×100 microns, each pixel separated from its neighbors by about 10 microns. The adhesive tie layer had a thickness of less than 0.5 micron and was applied by dipping the bottom pixel electrodes of the substrate into a dilute solution of the adhesive from which the solvent was subsequently allowed to evaporate.

The adhesive coated TFT substrate was then placed in a die press similar to the one shown in FIG. 3, and the mercuric iodide—polystyrene composite mixture was deposited on top of the Humiseal® tie layer. The detector plate had a final thickness of 150 microns and an active area of 2″×2″. Placing a spacer having the desired thickness in the die controlled the thickness of the plate.

The detector plate was then removed from the die and allowed to dry at room temperature. After drying, a continuous upper electrode of gold was applied by vacuum evaporation. A thin Pt wire was attached to the upper continuous electrode using a conductive glue, the Pt wire serving as a high voltage bias contact.

Surprisingly, it has been found that the sensitivity of PIB composite detectors discussed herein above can be maintained over longer time periods when a separate base layer is used. The base layer is placed adjacent to the bottom electrode and/or substrate and underneath a primary composite layer. Typically, the primary layer is a mercuric iodide PIB composite layer but other semiconductor PIB composite layers can also be used. The base layer, hereinafter called a “buffer” layer, typically is a lead iodide PIB composite layer. Alternatively, other “buffer” layers such as bismuth iodide or thallium bromide PIB composite layers can be used. The preparation of these layers and their application to the electrode or substrate have been described herein above. Where necessary, an adhesive layer comprised of any of the adhesives discussed above can be used to adhere the buffer layer to the electrode or substrate. Additionally, where necessary to prevent delamination, an adhesive layer can be positioned between the buffer and primary layers. These mixed semiconductor PIB composite multilayer detectors may hereafter be called “hybrid detectors”.

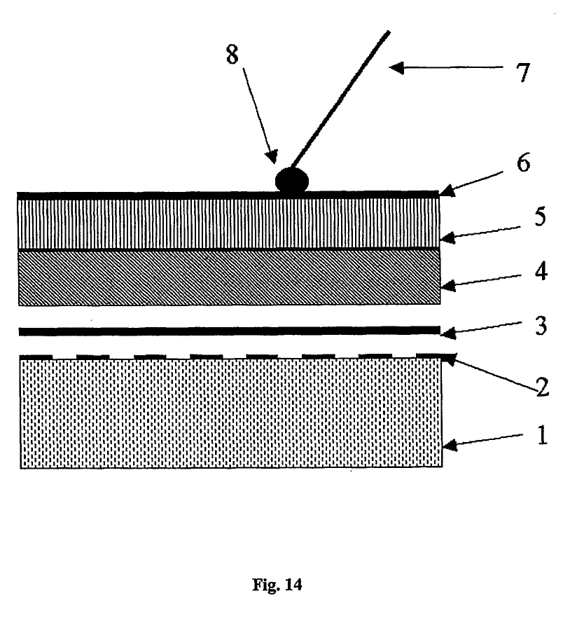

Reference is now made to FIG. 14 where a photoconducting hybrid bi-layer detector plate 10 for an X-ray imaging system produced according to the present invention is shown. Detector plate 10 consists of a TFT substrate 1 having metallic pixels (not shown), the latter functioning as the bottom electrode of detector 10. The bottom pixel electrode is coated with a tie layer 3, such as Humiseal® 1B12 (a polyacrylic, polyvinyl mixture in a mixed methyl ethyl ketone/toluene solvent). Tie layer 3 acts as an adhesive to prevent a Pbl₂ PIB layer 4 from peeling off the electrode. Tie layer 3 is usually less than 0.5 micron and is generally applied by dipping the substrate into a dilute solution of the adhesive, from which the solvent is then allowed to evaporate. Alternatively, tie layer 3 can be painted onto the upper surface of the bottom pixel electrode.

A PIB layer consisting of a Hgl₂ PIB composite 5 is applied directly onto the PIB buffer layer 4 consisting of Pbl₂ PIB composite 5. Both PIB layers 4 and 5 can be applied by any of the methods described herein. These methods include, but are not limited to, use of a doctor blade, die press, Mayer blade, slot coater or screen printer (SP). A vacuum deposited, painted or sprayed continuous upper electrode 6 covers mercuric iodide PIB composite layer 5 on the side distal from substrate 1. A high voltage platinum bias wire 7 is attached to upper electrode 6 using any suitable conductive glue 8. A number of such glues are commercially available. Optionally, the complete detector plate 10 can be encapsulated, as described above, with insulating, Inert material (not shown) and connected to a pixel array readout unit. The device in FIG. 14 can form part of the typical pixel equivalent circuit 40 shown in FIG. 2 discussed above.

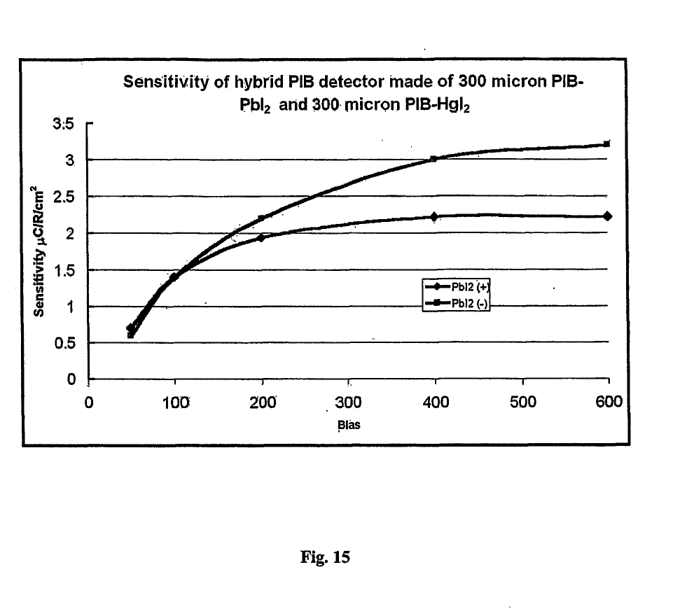

Reference is now made to FIG. 15 where the sensitivity versus bias polarity of a Hgl₂/Pbl₂/substrate hybrid is shown. The relative small differences in sensitivities when the two polarities are used is readily apparent. The bi-polarity enables easier application of these composites to TFT's designed for positive polarity. Theoretically, exploiting this bi-polarity allows for greater charge collection efficiency.

In the above description of multiple layers, the discussion has focused on bi-layer structures. It should readily be apparent to one skilled in the art that, when necessary, there can be more than two semiconductor PIB layers in a detector. For example, there may be occasions when a lead iodide PIB layer (or a bismuth iodide PIB layer or a thallium bromide PIB layer or a CZT PIB layer) is placed above a mercuric iodide PIB layer, proximate to the upper conducting electrode, forming a tri-layer.

In yet other embodiments the layers need not be discrete layers. A substantially uniform mixture of two or more different semiconductor PIB composites can be made and applied directly over an electrode and/or substrate. The resulting mixture of semiconductor PIBs can have the desirable feature of increasing the effective working-life of a detector without significantly reducing sensitivity.

### EXAMPLE 15

Ten grams of Pbl₂ powder, prepared as in Example 7 above, was mixed with about 3 ml of 25 wt % polystyrene/toluene solution resulting in a yellow paste. A 200 micron thick layer of this lead iodide PIB paste was die pressed onto the surface of a 1″×3″ indium-tin oxide (ITO) coated glass substrate that had been placed in a die mold as illustrated in FIG. 3 and discussed hereabove.

Equal volumes of a 0.6 M aqueous solution of HgCl₂ and a 1.2 M aqueous solution of KI were mixed quickly in a beaker and left to stand. The Hgl₂ which precipitated out was washed with water, filtered and dried. Ten grams of the dried Hgl₂ were mixed with about 3 ml of a 25 wt % polystyrene/toluene solution. The weight ratio of dry polystyrene to semiconductor in the composite was 15.4:1, corresponding to a volume ratio of polystyrene/Hgl₂ of 30:70. A homogenous paste was obtained.

The mercuric iodide/polystyrene PIB colloidal dispersion was cast on top of the Pbl₂ PIB ITO coated substrate previously prepared and placed in a die press. The Pbl₂ PIB composite coating the substrate was prepared as described in Example 9. The mercuric iodide PIB composite layer was pressed onto the lead iodide layer and a bi-layer “hybrid” detector plate was produced.

At the outset, prior to depositing the lead iodide layer, the substrate was coated with ITO to which a thin adhesive tie layer (Humiseal® 1B12) was applied. The ITO layer acted as the bottom pixel electrode. Each pixel had a size of about 100×100 microns and was separated by about 10 microns from its nearest neighbors in each direction. The adhesive tie layer had a thickness of less than 0.5 micron and was applied by dipping the bottom pixel electrodes of the substrate into a dilute solution of the adhesive, after which the solvent was allowed to evaporate. The adhesive tie layer acted as a glue preventing peeling of the lead iodide PIB buffer layer from the bottom pixel electrodes.

The detector plate was then removed from the die press and allowed to dry at room temperature. After drying, a continuous upper electrode of gold was applied by vacuum evaporation. A thin Pt wire was attached to the upper continuous electrode using a conductive glue; the Pt wire served as a high voltage bias contact.

The final, overall thickness of the detector plate thus formed was 400 microns. Placing spacers in the die controlled the thickness of the PIB layer.

### EXAMPLE 16

As in Example 15, except that the PIB buffer layer was a composite Bil₃ layer prepared according to the method described in Example 13.

### EXAMPLE 17

As in Example 15, but instead of applying the Pbl₂ PIB buffer layer and the Hgl₂ PIB layer using a die press, the PIB layers were applied with a doctor blade assembly similar to the one shown in FIG. 3.

### EXAMPLE 18

As in Example 15, but instead of applying the Pbl₂ PIB buffer layer and the Hgl₂ PIB layer using a die press, the PIB layers were applied by a screen printing apparatus similar to the one shown in FIG. 5.

### EXAMPLE 19

As in Example 15, but instead of depositing the Pbl₂ PIB buffer layer and the Hgl₂ PIB layer onto a TFT substrate array, the mixture was cast on a CCD pixel array with pixel dimensions similar to that disclosed in Example 15.

### EXAMPLE 20

As in Example 15, but instead of using polystyrene as the binder in the PIB composite, Humiseal®, a polyacrylic-polyvinyl polymeric mixture, diluted with a toluene/methyl ethyl ketone mixed solvent, was used. The Humiseal®/semiconductor ratio was the same as in Example 15 and the detector was pressed in a die press.

### EXAMPLE 21

As in Example 15, but instead of using vacuum evaporated gold as the continuous upper electrode, magnetron sputtered gold was used as the continuous upper electrode.

### EXAMPLE 22

Bil₃ powder and a bismuth iodide BIP composite made from that powder were prepared as in Example 13. The resulting black paste was spread onto an ITO coated glass substrate that was been pre-coated with an adhesive tie layer material. The PIB covered substrate was compressed to a desired thickness by pressing the PIB covered substrate in a die-press thereby forming a buffer layer. After drying in air for 4 days, a Hgl₂ PIB composite layer similar to that obtained in Example 1 was placed as a primary layer over the Bil₃—PIB composite and spread to the desired thickness using a doctor blade assembly. A gold electrode was applied using sputtering.

While the present invention has been described herein above in terms of wide band gap semiconductors synthesized by precipitation from solution, the method of preparation discussed and the examples described should be viewed as illustrative only and non-limiting. It is readily appreciated by one skilled in the art that any method of preparing these wide band gap semiconductors which results in small grains of the size defined herein, can also be used.

Imaging systems made with detector plates using the composites or hybrid composites of the present invention can have a multiplicity of uses. Among these applications are mapping X-ray emission and gamma bursts from solar and extra-galactic sources, identification of counterfeit banknotes, identifying paintings and archeological artifacts and detecting nuclear materials. These systems can be used in nuclear medicine and in operating procedures such as tumor removal, transplant perfusion, vascular graft viability, among others. Because the plates do not contain single crystal materials, they can be used to fabricate the large detectors required in many applications at substantially reduced cost.

It will be appreciated by persons skilled in the art that the present invention is not limited to what has been particularly shown and described hereinabove. Rather the scope of the present invention is defined only by the claims that follow:

1. An imaging composition for radiation detection systems which comprises an admixture of at least one non-heat treated, non-ground particulate semiconductor with a polymeric binder, said at least one non-heat treated, non-ground particulate semiconductor selected from a group consisting of mercuric iodide, lead iodide, bismuth iodide, thallium bromide and cadmium-zinc-telluride (CZT), and wherein at least 90% of said semiconductor particulates have a grain size of less than 100 microns in their largest dimension.

2. An imaging composition according to claim 1, which possesses at least one of the following features:
(i) said polymeric binder is an organic polymeric binder;
(ii) at least 90% of said semiconductor particulates have a grain size of less than 15 microns in their largest dimension;
(iii) said composition further comprises at least one organic solvent;
(iv) the weight ratio of said semiconductor particulates to said binder is from about 4.4:1 to about 26.0:1.

3. An imaging composition according to claim 2, which possesses at least one of the following features:
(i) said organic polymeric binder comprises at least one polymer selected from a group consisting of polystyrene, polyurethane, alkyd polymers, cellulose polymers, and acrylic and vinyl polymers and co-polymers and mixtures thereof;
(ii) at least 90% of said semiconductor particulates have a grain size of less than 10 microns in their largest dimension;
(iii) said at least one organic solvent is selected from aliphatic alcohols, ethers, esters, ketones and aromatic and heterocyclic solvents;
(iv) the weight ratio of said semiconductor particulates to said binder is from about 6.6:1 to about 19.8:1.

4. An imaging composition according to claim 2, which possesses at least one of the following features:
(i) said organic polymeric binder comprises at least one polymer selected from a group consisting of polystyrene, polyurethane, and acrylic and vinyl homo- and co-polymers and mixtures thereof;
(ii) at least 90% of said semiconductor particulates have a grain size of less than 5 microns in their largest dimension;
(iii) said at least one organic solvent is selected from aliphatic alcohols, ethers, esters, ketones and aromatic and heterocyclic solvents;
(iv) the weight ratio of said semiconductor particulates to said binder is from about 9:1 to about 15.4:1.

5. An imaging composition according to claim 1, wherein said semiconductor particulates are precipitated from a solution.

6. An imaging composition according to claim 5, wherein said solution has a solvent which is chosen from a group consisting of water, a non-aqueous solvent, a mixed aqueous-non-aqueous solvent and a mixed non-aqueous solvent.

7. A radiation detector plate for an imaging system including:
at least one substrate, said substrate serving as an electrode;
at least one imaging composition layer of an imaging composition applied onto said substrate, said composition including:
at least one particulate semiconductor, said semiconductor comprising non-ground, non-heat treated particulates at least 90% of which are below 100 microns in their largest dimension and wherein said semiconductor is chosen from a group consisting of bismuth iodide, lead iodide, mercuric iodide, thallium bromide and cadmium-zinc-telluride (CZT); and
a polymeric binder, said semiconductor particulates being in an admixture with said binder; and
a second electrode, said second electrode in electrical connection with said composition and connected to a high voltage bias.

8. A radiation detector plate according to claim 7, which additionally comprises at least one composition layer comprising non-heat treated, non-ground particulate mercuric iodide in admixture with a polymeric binder.

9. A radiation detector plate according to claim 7, wherein said at least one composition layer comprises at least two semiconductors selected from a group consisting of bismuth iodide, lead iodide, mercuric iodide, thallium bromide and cadmium-zinc-telluride (CZT).

10. A radiation detector plate according to claim 7, wherein said at least one composition layer comprises at least two discrete composition layers, each of said discrete layers comprised of at least one semiconductor selected from a group consisting of bismuth iodide, lead iodide, mercuric iodide, thallium bromide and cadmium-zinc-telluride (CZT).

11. A radiation detector plate according to claim 10, further including an adhesive layer between said at least two discrete composition layers.

12. A radiation detector plate according to claim 10, wherein said at least two discrete composition layers comprise at least one discrete composition layer in which said semiconductor is non-heat treated, non-ground particulate lead iodide and at least one discrete composition layer in which said semiconductor is non-heat treated, non-ground particulate mercuric iodide.

13. A radiation detector plate according to claim 7, which further comprises an adhesive tie layer applied to said substrate.

14. A radiation detector plate according to claim 13, wherein said tie layer is chosen from a group consisting of polyacrylics, polyvinyls, polyurethanes, polyimides, cyanoacrylics, silanes, polyesters, and neoprene rubbers and mixtures thereof to bind said composition layer to said substrate.

15. A radiation detector plate according to claim 13, wherein said tie layer is a polyacrylic-polyvinyl mixture.

16. A radiation detector plate according to claim 13, wherein said tie layer is a silane.

17. A radiation detector plate according to claim 13, wherein said composition layer is applied onto said adhesive layer on the side of said adhesive layer distal from said substrate.

18. A radiation detector plate according to claim 7, wherein said at least one substrate is coated with a uniform, thin film of electrically conducting material selected from a group consisting of palladium, gold, platinum, indium-tin oxide (ITO) and germanium.

19. A radiation detector plate according to claim 7, wherein said second electrode comprises a uniform, thin film of electrically conducting material selected from a group consisting of carbon, palladium, gold, platinum, indium-tin oxide (ITO) and germanium.

20. A radiation detector plate according to claim 7, wherein said second electrode is applied by a method selected from a group consisting of sputtering, evaporation, spraying and painting.

21. A radiation detector plate according to claim 7, wherein said at least one substrate is chosen from a group consisting of a thin film transistor (TFT) flat panel array, a charge coupled device (CCD), complementary metal oxide semiconductor (CMOS) array and an application specific integrated circuit (ASIC).

22. A radiation detector plate according to claim 7, wherein said at least one composition layer possesses at least one of the following features:
(i) said polymeric binder is an organic binder;
(ii) at least 90% of said semiconductor particulates have a grain size of less than 15 microns in their largest dimension.

23. A radiation detector plate according to claim 22, wherein said at least one composition layer possesses at least one of the following features:
(i) said organic polymeric binder comprises at least one polymer selected from a group consisting of polystyrene, polyurethane, alkyd polymers, cellulose polymers, and acrylic and vinyl homo- and co-polymers and mixtures thereof;
(ii) at least 90% of said semiconductor particulates have a grain size of less than 10 microns in their largest dimension.

24. A radiation detector plate according to claim 22, wherein said at least one composition layer possesses at least one of the following features:
(i) said organic polymeric binder comprises at least one polymer selected from a group consisting of polystyrene, polyurethane, and acrylic and vinyl homo- and co-polymers and mixtures thereof;
(ii) at least 90% of said semiconductor particulates have a grain size of less than 5 microns in their largest dimension.

25. A radiation detector plate according to claim 7, wherein said at least one composition layer is prepared at room temperature.

26. A radiation detector plate according to claim 7, wherein said at least one composition layer is prepared at temperatures below 60° C.

27. A radiation detector plate according to claim 7, wherein said at least one composition layer has a thickness of 40-3000 microns.

28. A radiation detector plate according to claim 7, wherein said system can detect radiation in the 6 keV to 15 MeV range.

29. An image receptor for an imaging system, comprising at least one composition layer, said layer comprising an imaging composition as defined in claim 1, said composition layer positioned on a conductive substrate layer, said substrate layer forming a bottom electrode, and said composition layer covered by an upper conductive layer forming an upper electrode, wherein at least one of said conductive layers is provided with a plurality of conductive areas separated from each other by a plurality of non-conductive areas, and wherein a multiplicity of said conductive areas are individually, connected, via a charge-sensitive pre-amplifier, to an imaging electronic system.

30. An image receptor according to claim 29, which is further characterized by at least one of the following features:
(i) said conductive areas are separated from each other by a dielectric material;
(ii) said conductive substrate layer is covered with a uniform, thin film electrode layer selected from a group consisting of palladium, gold, platinum, indium-tin oxide (ITO) and germanium;
(iii) said image receptor is adapted for use in an imaging system selected from X-ray and gamma ray imaging systems;
(iv) in said at least one composition layer, said polymeric binder is an organic binder;
(v) in said at least one composition layer, at least 90% of said semiconductor particulates have a grain size of less than 15 microns in their largest dimension;
(vi) an adhesive tie layer between said composition layer and said bottom electrode, said tie layer chosen from a group consisting of polyacrylics, polyvinyls, polyurethanes, polyimides, cyanoacrylics, silanes, polyesters, and neoprene rubbers and mixtures thereof to bind said composition layer to said electrode.

31. An image receptor according to claim 30, wherein said at least one composition layer possesses at least one of the following features:
(i) said organic polymeric binder comprises at least one polymer selected from a group consisting of polystyrene, polyurethane, alkyd polymers, cellulose polymers, and acrylic and vinyl homo- and co-polymers;
(ii) at least 90% of said semiconductor particulates have a grain size of less than 10 microns in their largest dimension;
(iii) comprises at least one polymer selected from a group consisting of polyurethane, polystyrene, and acrylic and vinyl homo- and co-polymers.

32. An image receptor according to claim 30, wherein said at least one composition layer possesses at least one of the following features:
(i) said organic polymeric binder comprises at least one polymer selected from a group consisting of polystyrene, polyurethane, alkyd polymers, cellulose polymers, and acrylic and vinyl homo- and co-polymers;
(ii) at least 90% of said semiconductor particulates have a grain size of less than 5 microns in their largest dimension;
(iii) comprises at least one polymer selected from a group consisting of polyurethane, polystyrene, and acrylic and vinyl homo- and co-polymers.

33. An image receptor according to claim 29, which additionally comprises at least one composition layer comprising non-heat treated, non-ground particulate mercuric iodide in admixture with an organic polymeric binder.

34. An image receptor according to claim 29, wherein said at least one composition layer comprises at least two said semiconductors selected from bismuth iodide, lead iodide, mercuric iodide, thallium bromide and cadmium-zinc-telluride (CZT).

35. An image receptor according to claim 29, wherein said at least one composition layer comprises at least two discrete composition layers, each of said discrete layers comprised of at least one semiconductor selected from a group consisting of bismuth iodide, lead iodide, mercuric iodide, thallium bromide and cadmium-zinc-telluride (CZT).

36. An image receptor according to claim 35, further comprising an adhesive layer between said two discrete composition layers.

37. An image receptor according to claim 35, wherein said at least two discrete composition layers comprise at least one discrete composition layer where said semiconductor is non-heat treated, non-ground particulate lead iodide and at least one discrete composition layer where said semiconductor is non-heat treated, non-ground particulate mercuric iodide.

38. An image receptor according to claim 29, wherein said substrate is chosen from a group consisting of a thin film transistor (TFT) flat panel array, a charge coupled device (CCD), complementary metal oxide semiconductor (CMOS) array and an application specific integrated circuit (ASIC).

39. An image receptor according to claim 29, wherein said receptor is prepared at room temperature.

40. An image receptor according to claim 29, wherein said receptor is prepared at temperatures below 60° C.

41. An image receptor according to claim 29, wherein said receptor can image radiation from about 6 keV to about 15 MeV.

42. A method for preparing a radiation detector plate, said method including the steps of:
providing a substrate;
placing a semiconductor imaging composition onto said substrate thereby forming a composition layer, wherein the imaging composition comprises an admixture of at least one non-heat treated, non-ground particulate semiconductor with a polymeric binder, said at least one non-heat treated, non-ground particulate semiconductor selected from a group consisting of mercuric iodide, lead iodide, bismuth iodide, thallium bromide and cadmium-zinc-telluride (CZT), and wherein at least 90% of said semiconductor particulates have a grain size of less than 100 microns in their largest dimension:
applying an electrode to said composition layer on the side distal from said substrate; and
connecting a high voltage bias connection to said electrode.

43. A method for preparing a radiation detector plate according to claim 42, further comprising the step of applying an adhesive tie layer to said substrate prior to said placing step.

44. A method for preparing a radiation detector plate according to claim 42, wherein said placing step further comprises a step of die pressing said composition to form said composition layer.

45. A method for preparing a radiation detector plate according to claim 42, wherein said placing step further comprises a step of slot die coating said composition to form said composition layer.

46. A method for preparing a radiation detector plate according to claim 42, wherein said placing step further comprises a step of spreading said composition with a doctor blade to form said composition layer.

47. A method for preparing a radiation detector plate according to claim 42, wherein said placing step further comprises a step of spreading said composition with a Mayer rod to form said composition layer.

48. A method for preparing a radiation detector plate according to claim 42, wherein said placing step further includes the step of screen printing said composition to form said composition layer.

49. A method for preparing a radiation detector plate according to claim 42, wherein said placing step includes a series of placing steps each of said steps forming another composition layer.

50. A method for preparing a radiation detector plate according to claim 42, further comprising the step of depositing an electrically conductive material on said substrate before said placing step.
